(19) United States
(12) Patent Application Publication
(10) Pub. No.: US 2012/0159286 A1
(43) Pub. Date: Jun. 21, 2012

(54) DATA TRANSMISSION DEVICE, MEMORY CONTROL DEVICE, AND MEMORY SYSTEM

(75) Inventor: Junichi Koshiyama, Tokyo (JP)

(73) Assignee: SONY CORPORATION, Tokyo (JP)

(21) Appl. No.: 13/312,515

(22) Filed: Dec. 6, 2011

(30) Foreign Application Priority Data
Dec. 17, 2010 (JP) 2010-281566

(51) Int. Cl. G11C 29/00; G06F 11/16

(52) U.S. Cl. 714/768; 714/E11.055

(57) ABSTRACT

There is provided a data transmission device including a data information storage area including a plurality of areas for storing a first memory address of the first memory device of a data transmission source, a second memory address of the second memory device of a data transmission destination, an error signal indicating whether or not an error is detected in transmission data, and an validity signal indicating whether or not data stored in the second memory device are valid after completing the error correction; and a control unit that outputs a second memory validity address which is a memory address in which data are valid out of data stored in the second memory device, reads data from the second memory validity address of the second memory device, and transmits an address of the first memory device corresponding to the second memory validity address along with the read data.

### BACKGROUND

The present disclosure relates to a data transmission device, a memory control device, and a memory system capable of accessing a nonvolatile memory and the like and having an error correction function.

In order to increase reliability of data written to the memory, the error correction code (ECC) is used as shown in FIG. 16.

Particularly, in the nonvolatile memory, if data are repeatedly read or the storage period increases after writing the data, the stored data may be deteriorated, or correct data may not be read due to bit corruption.

For this reason, a memory controller for controlling the nonvolatile memory improves data reliability by writing data with the error correction code (ECC) added to the written data and performing error detection and correction at the time of reading.

Meanwhile, if an error occurs in the read data, a certain period of time is necessary in the correction process thereof, and it is difficult to output the data externally from the memory controller until the correction is completed so that the output of data is delayed.

In this case, if subsequent data are present, the output of data is awaited. As a result, data read performance is degraded.

As NAND flash memory, which is one type of nonvolatile memory, has been miniaturized in the manufacturing process year by year, data reliability is degraded. Accordingly, the memory controller necessitates an error correction circuit having a higher correction capability.

However, as shown in FIG. 17, due to a high error correction capability or a larger unit of data used to apply the ECC, a time for the error correction process increases. When correction occurs in the read data, the data read performance is further degraded.

Japanese Unexamined Patent Application Publication No. 2000-57063 discloses a technique of improving performance of the read data, in which a plurality of buffer RAMs are provided, and the next data are read to the empty buffer while the error correction is performed.

### SUMMARY

However, in the aforementioned technique, the error correction is performed in order of the data read from the memory, and the data are transmitted to a host system apparatus. Therefore, if error correction occurs, data transmission to the host system is inevitably delayed.

It is desirable to provide a data transmission device, a memory control device, and a memory system capable of reducing the data transmission delay time and the time necessary to transmit data even when error correction occurs.

According to an embodiment of the present disclosure, there is provided a data transmission device including: a second memory device that stores data transmitted from a first memory device that stores data incorporating an error correction code (ECC); an error detection unit that detects an error using data before the correction and the error correction code (ECC); an error correction unit that obtains an error position from error information and an error detection signal from the error detection unit and corrects error data based on an address of the second memory device to which data containing an error are written and error position information; a data information storage area including a plurality of areas for storing a first memory address of the first memory device of a data transmission source, a second memory address of the second memory device of a data transmission destination, an error signal indicating whether or not an error is detected in transmission data, and an validity signal indicating whether or not data stored in the second memory device are valid after completing the error correction; and a control unit that outputs a second memory validity address which is a memory address in which data are valid out of data stored in the second memory device, reads data from the second memory validity address of the second memory device, and transmits an address of the first memory device corresponding to the second memory validity address along with the read data.

According to another embodiment of the present disclosure, there is provided a memory control device including: at least one data transmission device that performs data transmission between first memory devices; and a memory controller that performs transmission control with at least a host device, wherein the data transmission device includes a second memory device that stores data transmitted from the first memory device that stores data incorporating an error correction code (ECC), an error detection unit that detects an error based on data before correction and an error correction code (ECC), an error correction unit that obtains an error position based on error information and an error detection signal from the error detection unit, and corrects error data based on error position information and an address of the second memory device to which data containing an error have been written, a data information storage area having a plurality of areas for storing a first memory address of the first memory device of the data transmission source, a second memory address of the second memory device of a data transmission destination, an error signal indicating whether or not an error has been detected in transmission data, and an validity signal indicating whether or not data stored in the second memory device are valid after completing the error correction, and a first control unit that outputs a second memory validity address which is a memory address in which data are valid out of the data stored in the second memory device, reads data from a second memory validity address of the second memory device, and transmits an address of the first memory device corresponding to the second memory validity address along with the read data, and wherein the memory controller includes an address control unit that receives a read command from the host device, converts a read logic address into a first memory physical address and converts the physical address into a logical address, and a transmission control system that also transmits a logical address when data are output to the host device and notifies a host of an interrupt signal indicating that data transmission is completed when transmission of data having a size requested by the read command is completed.

According to still another embodiment of the present disclosure, there is provided a memory system including: a host device; a first memory device that stores data incorporating an error correction code (ECC); and a memory control device that performs data transmission control between the host device and the first memory device, wherein, the memory control device has at least a data transmission device that performs data transmission between first memory devices, and a memory controller that performs transmission control with at least one host device, wherein the data transmission device has a second memory device that stores data transmitted from the first memory device which stores the data incorporating the error correction code (ECC), an error detection unit that detects an error using the data before correction and the error correction code (ECC), an error correction unit that obtains an error position from error information and an error detection signal from the error detection unit, and corrects error data based on error position information and an address of the second memory device to which data containing an error have been written, a data information storage area having a plurality of areas for storing a first memory address of the first memory device of a data transmission source, a second memory address of the second memory device of a data transmission destination, an error signal indicating whether or not an error is detected in transmission data, and an validity signal indicating whether or not the data stored in the second memory device are valid after completing the error correction, and a first control unit that outputs a second memory validity address which is a memory address in which data are valid out of the data stored in the second memory device, reads data from the second memory validity address of the second memory device, and transmits an address of the first memory device corresponding to the second memory validity address along with the read data, and wherein the memory controller includes an address control unit that receives a read command from the host device, converts the read logical address into a first memory physical address and converts a physical address into a logical address, and a transmission control system that also transmits a logical address when data are output to the host device, and notifies the host of an interrupt signal indicating that data transmission is completed when transmission of data having a size requested by the read command is completed.

According to the embodiments of the disclosure, it is possible to reduce the data transmission delay time and the time necessary to transmit data even when error correction occurs.

### BRIEF DESCRIPTION OF THE DRAWINGS

FIG. 1 is a diagram illustrating a configuration of the memory system obtained by applying a data transmission device according to a first embodiment of the disclosure.

FIG. 2 is a flowchart illustrating a reading process of the first memory device and a process of controlling the read data information storage area according to the first embodiment of the disclosure.

FIG. 3 is a flowchart illustrating a process of reading data from the second memory unit externally according to first embodiment of the disclosure.

FIGS. 4A to 4E are diagrams illustrating a condition of the read data information storage area during reading from the first memory device according to the first embodiment of the disclosure.

FIG. 5 is a diagram illustrating a configuration of the memory system obtained by applying a data transmission device according to a second embodiment of the disclosure.

FIG. 6 is a diagram illustrating a fundamental characteristic of a NAND flash memory.

FIG. 7 is a diagram illustrating a command format example.

FIG. 8 is a diagram illustrating a configuration of the memory system obtained by applying a data transmission device according to a third embodiment of the disclosure.

FIG. 9 is a diagram illustrating a configuration of the memory system obtained by applying a data transmission device according to a fourth embodiment of the disclosure.

FIG. 10 is a diagram illustrating a configuration of the memory system obtained by applying a data transmission device according to a fifth embodiment of the disclosure.

FIG. 11 is a diagram illustrating a packet format used in PCI Express.

FIG. 12 is a diagram illustrating data transmission between the memory controller and the host device and data transmission between the memory controller and the nonvolatile memory according to a fifth embodiment of the disclosure.

FIG. 13 is a diagram illustrating a configuration of the memory system obtained by applying a data transmission device according to a sixth embodiment of the disclosure.

FIG. 14 is a diagram illustrating an effect of first output of no error data according to an embodiment of the disclosure.

FIG. 15 is a diagram illustrating an effect of first output of no error data in a case where a plurality of nonvolatile memory I/Fs are provided according to an embodiment of the disclosure.

FIG. 16 is a diagram illustrating a case where the error correction code (ECC) is used in order to improve reliability of data written to the memory.

FIG. 17 is a diagram illustrating a case where the unit of data used to apply the ECC increases.

### DETAILED DESCRIPTION OF EMBODIMENTS

Hereinafter, embodiments of the disclosure will be described with reference to the accompanying drawings.

Description will be made in the following sequence.

1. First Embodiment

2. Second Embodiment

3. Third Embodiment

4. Fourth Embodiment

5. Fifth Embodiment

6. Sixth Embodiment

### 1. First Embodiment

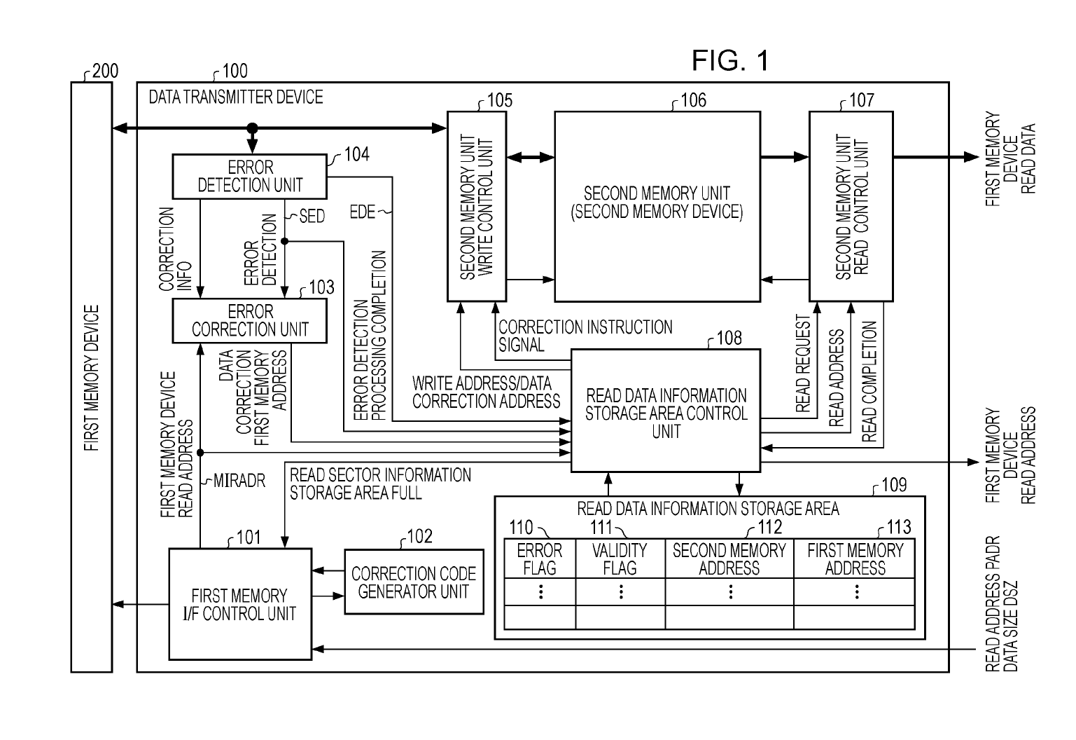

FIG. 1 is a diagram illustrating a configuration of a memory system obtained by applying a data transmission device according to a first embodiment of the disclosure.

The memory system 10 includes a data transmission device 100 and a first memory device 200.

The data transmission device 100 according to the present embodiment reads data from the first memory device 200 and transmits the data externally.

The data transmission device 100 includes a first memory device interface (I/F) control unit 101, a correction code generation unit 102, an error correction unit 103, an error detection unit 104, a second memory unit write control unit 105, and a second memory unit 106 as a second memory device.

The data transmission device 100 includes a second memory unit read control unit 107, a read data information recording area control unit 108, and a read data information storage area 109.

The read data information storage area 109 stores the address (second memory address 112) of the second memory unit 106 where the data read from the first memory device 200 are stored and the memory address (first memory address 113) of the first memory device 200.

The read data information storage area 109 stores an error flag 110 indicating that an error is detected in the data read from the first memory device 200 and an validity flag 111 indicating that the data stored in the second memory unit 106 are valid after completing the error correction.

When the data are written to the first memory device 200, the data transmission device 100 receives a write address and data from an outer side, and the error correction code (ECC) generation unit 102 generates the error correction code (ECC) for the write data.

In addition, in the data transmission device 100, the first memory device I/F control unit 101 controls the memory interface and writes the write data and the error correction code (ECC) in the first memory device 200.

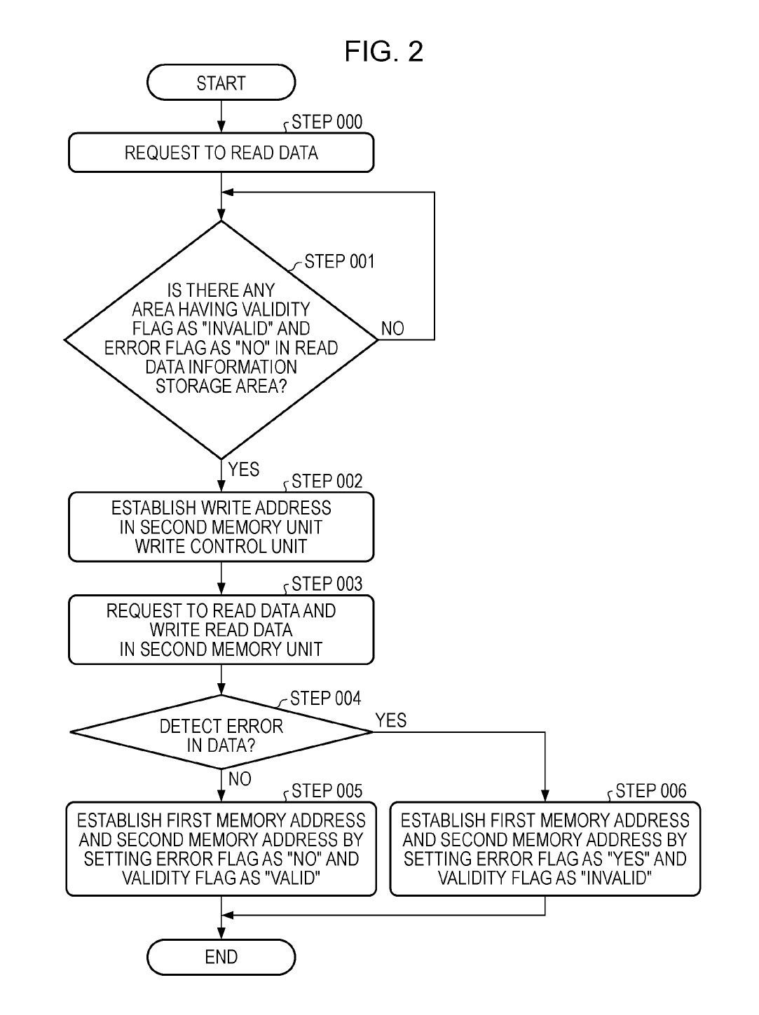

Here, a process until the data are read from the first memory device 200 to the second memory unit 106 will be described with reference to FIG. 2.

FIG. 2 is a flowchart illustrating a process of reading the first memory device and controlling the read data information storage area according to the first embodiment of the disclosure.

When the data are read from the first memory device 200, the data transmission device 100 receives the read address RADR and the data size DSZ from an outer side (STEP 000).

If an area having an validity flag 111 set as “INVALID” and an error flag 110 set as “NO” exists in the read data information storage area 109, this is a case where an empty area exists in the second memory unit 106. If there is an empty area in the second memory unit 106 (STEP 001), the first memory device I/F control unit 101 controls the memory interface to receive data from the read address of the first memory device 200.

The read data is written to the address of the second memory unit 106 designated by the read data information recording area control unit 108 (STEP 002 and STEP 003), and an error in the read data is checked in parallel using the error detection unit 104.

If no error is detected in the read data (NO in STEP 004), the first memory device read address, the error detection processing completion, and the no-error detection are notified to the read data information recording area control unit 108.

As the read data information recording area control unit 108 receives the first memory device read address M1RADR, the error detection processing completion EDE, and the no-error detection signal, the following processing is performed.

The validity flag 111 corresponding to the address designated in the write address of the second memory unit 106 is set to “VALID,” the error flag 110 is set to “NO,” the read address of the first memory device 200 is set to the first memory address 113, and the address of the second memory device 106 where the read data are written is set to the second memory address 112 (STEP 005).

Here, the address written to the first memory address 113 and the write address of the second memory unit 106 are aligned in the unit of data used to apply the ECC.

For example, if the unit used to apply the ECC is 512 bytes, the write address is a multiple of 0x200, and the lowermost 9 bits of the address are set to zero.

Meanwhile, if an error is detected in the read data (YES in STEP 004), the first memory device read address M1ARADR, the error detection processing completion EDE, and the error detection signal SED are notified to the read data information recording area control unit 108.

As the read data information recording area control unit 108 receives the first memory device read address, the error detection processing completion, and the error detection, the following process is performed.

The validity flag 111 corresponding to the address designated in the write address of the second memory unit 106 is set to “INVALID,” the error flag 110 is set to “YES,” the read address of the first memory device 200 is set to the first memory address 113, and the address of the second memory device 106 to which the read data are written is set to the second memory address 112 (STEP 006).

Next, the process of error correction in the data transmission device 100 will be described.

As the error correction unit 103 receives the error detection, the error information and the first memory device read address M1RADR are stored, the error detection is performed, and the first memory device read address necessary to data correction is output to the read data information recording area control unit 108.

Here, the error information refers to a syndrome value.

In addition, the error correction unit 103 has an area for storing a plurality of error information pieces and the first memory device read address MARADR.

As the read data information recording area control unit 108 receives the first memory device read address (data correction first memory address) for which data correction is necessarily performed, the following processing is performed.

The read data information recording area control unit 108 computes the second memory address 112 corresponding to the data correction first memory address from the first memory address 113 of the read data information storage area 109.

In addition, the read data information recording area control unit 108 outputs the second memory address for the data correction and the signal for declaring correction (correction instruction signal) to the second memory unit write control unit 105.

As the second memory unit write control unit 105 receives the second memory address of the data to be corrected and the correction instruction signal, the data are read from the second memory address to be corrected. In addition, the second memory unit write control unit 105 writes those data and the data obtained by reversing “0” and “1” to the second memory unit 106 and notifies the read data information recording area control unit 108 of the write completion.

The read data information recording area control unit 108 sets the error flag 110 corresponding to the second memory address 112 for which the correction has been completed out of the read data information storage area 109 to “NO,” and sets the validity flag 111 to “VALID.”

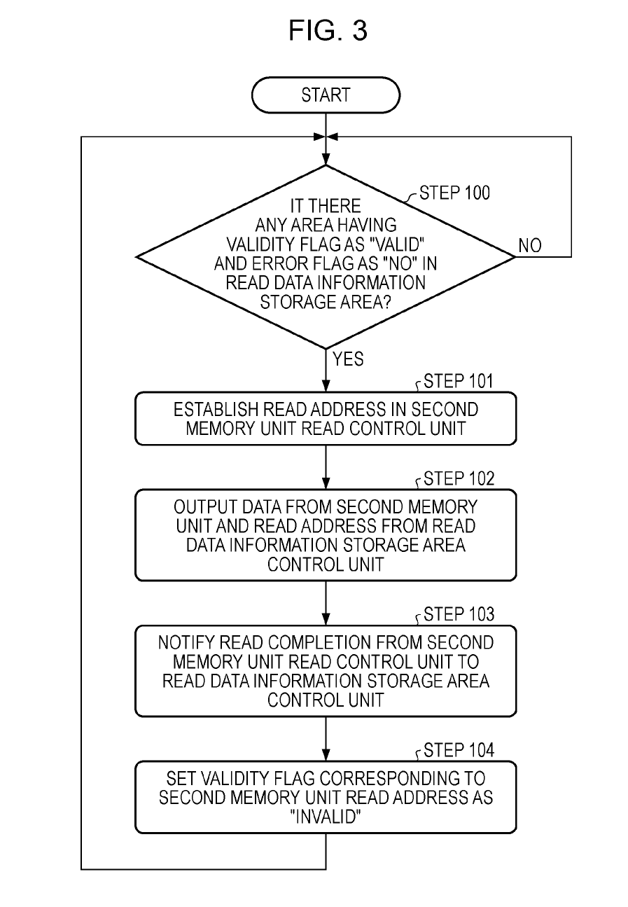

Next, the process of reading data from the second memory unit 106 externally will be described with reference to FIG. 3.

FIG. 3 is a flowchart illustrating a process of reading data externally from the second memory unit according to the first embodiment of the disclosure.

The read data information recording area control unit 108 performs the following processing if the second memory address 112 in which the validity flag 111 of the read data information storage area 109 is set to “VALID” exists (STEP 100).

The read data information recording area control unit 108 outputs the read address of the second memory unit 106 and the read request to the second memory unit read control unit 107 (STEP 101).

The second memory unit read control unit 107 receives the read request and reads and outputs the data from the designated second memory unit 106. The read address is output from the read data information recording area control unit 108 (STEP 102).

As the reading of data is completed, the second memory unit read control unit 107 notifies the read completion to the read data information recording area control unit 108 (STEP 103).

In addition, the read data information recording area control unit 108 receives notification of the read completion and sets the validity flag 111 corresponding to the read address of the second memory unit 106 to “INVALID” (STEP 104).

In addition, the error correction process in a case where an error exists in the read data from the first memory device 200 and the process of reading the next data from the first memory device 200 are performed in parallel.

The empty area in the aforementioned second memory unit 106 (STEP 001 of FIG. 2) is determined based on whether or not there is a second memory address 112 having an error flag 110 set to “NO” and an validity flag 111 set to “INVALID” in the read data information storage area 109 using the read data information recording area control unit 108.

If there is the empty area, the second memory address 112 thereof is notified to the second memory unit write control unit 105, and the data read from the first memory device 200 are written to the second memory unit 106.

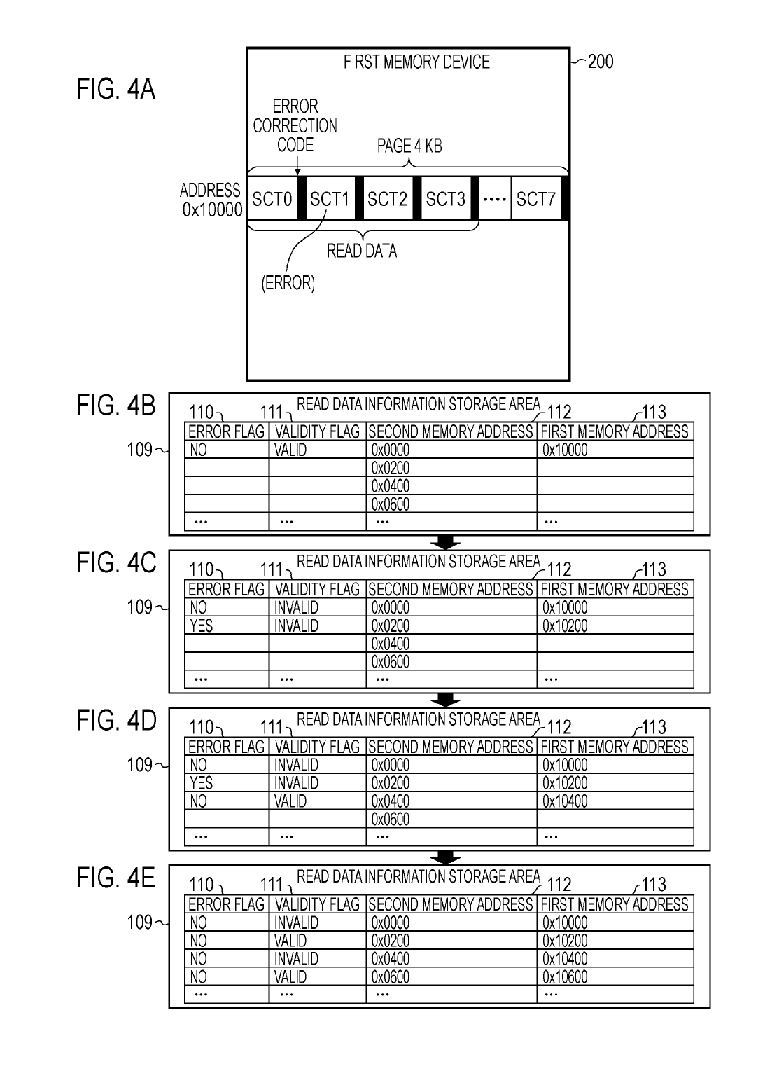

FIGS. 4A to 4E are diagrams illustrating in detail the state of the read data information storage area 109 when data are read from the first memory device 200 according to the first embodiment of the disclosure.

Specifically, as shown in FIG. 4A, the error correction code (ECC) is added to the data stored in the first memory device 200 for each 512-byte block (hereinafter, referred to as a sector) basis.

In a case where, out of the data of 2 KB from the address 0x10000 of the first memory device 200, an error exists in the sector SCT1 (address 0x10200), and no error exists in the sectors SCT0(0x10000), SCT2(0x10400), and SCT3(0x10600), the following process is performed.

In a case where the data of 4 sectors are read from the address 0x10000 of the first memory device 200, it is possible to determine the address (0x0000) of the second memory unit 106 where the data read from the first memory device 200 are written.

Then, the sector SCT0 is read from the first memory device 200. In this case, since there is no error, the error flag 110 of the read data information storage area 109 is set to “NO,” and the validity flag 111 is set to “VALID.” The second memory address 112 is set to “0x0000,” and the first memory address 113 is set to “0x10000” (FIG. 4B).

If the read data information having an validity flag 111 set to “VALID” is detected, the read data information recording area control unit 108 outputs the second memory address 112 “0x0000” to the second memory unit read control unit 107.

The second memory unit read control unit 107 reads data corresponding to one sector from the second memory address 112 “0x0000,” and the read data information recording area control unit 108 outputs the first memory address 112 “0x10000.”

If the data of one sector are completely read, the second memory unit read control unit 107 notifies the read data information recording area control unit 108 of the completion of the reading. The read data information recording area control unit 108 sets the validity flag 111 of the second memory address 112 “0x0000” to “INVALID.”

In parallel with the data reading from the second memory unit 106, the data of the sector SCT1 are read from the first memory device 200.

The address (0x0200) of the second memory unit 106 where the data of the sector SCT1 read from the first memory device 200 are written is determined, and the data of the sector SCT1 are read from the address “0x10200” of the first memory device 200.

Since an error is included in these data, an error is detected by the error detection unit 104. As shown in FIG. 4C, the error flag 110 of the read data information storage area 109 is set to “YES,” and the validity flag 111 is set to “INVALID.” In addition, the second memory address 112 is set to “0x0200,” and the first memory address 113 is set to “0x10200.”

In this state, since there is no data having the validity flag 111 set to “VALID,” reading of the data from the second memory unit 106 does not occur.

The error correction unit 103 receives error correction information (syndrome) from the error detection unit 104, and the error correction is performed. In parallel with the error correction, the data of the sector SCT2 are read from the first memory device 200.

The address (0x0400) of the second memory unit 106 where the data of the sector SCT2 read from the first memory device 200 are written is determined, and the data of the sector SCT2 are read from the address “0x10400” of the first memory device 200.

Since no error exists in these data, as shown in FIG. 4D, the error flag 110 of the read data information storage area 109 is set to “NO,” and the validity flag 111 is set to “EFFCTIVE.” In addition, the second memory address 112 is set to “0x0400,” and the first memory address 113 is set to “0x10400.”

In the state of FIG. 4D, since correction for the data of the second memory address 112 “0x0200” has not been completed, the data of the second memory address 112 “0x0400” are read first.

In parallel, the error correction is performed using the error correction unit 103, and the data of the sector SCT3 are read from the first memory device 200.

As error correction for the data of the second memory address 112 “0x0200” is completed, the address of the corrected first memory device 200 is notified to the read data information recording area control unit 108.

The read data information recording area control unit 108 searches for the first memory address 113 including the first memory address to be corrected and detects the second memory address 112 “0x0200” corresponding that from the first memory address 113 “0x10200.” A value obtained by adding second memory address 112 “0x0200” and the value obtained by subtracting the first memory address 113 “0x10200” from the first memory address to be corrected is output to the second memory unit write control unit 105 along with the correction instruction signal as a correction address.

The second memory unit write control unit 105 reads the data of the correction address received from the read data information recording area control unit 108 from the second memory unit and performs data correction by inverting the data and writing the data into the same address again. In a case where errors exist across a plurality of bits, the aforementioned process is performed until correction for all of the bits is completed.

As the writing of the correction data is completed, the second memory unit write control unit 105 notifies the read data information recording area control unit 108 of the write completion. The read data information recording area control unit 108 sets the error flag 110 corresponding to that address to “NO.”

Both the error correction of the data for the second memory address 112 “0x0200” and the reading of the data for the sector SCT3 from the first memory device 200 are completed until the reading of the data for the second memory address 112 “0x0400” is completed, the process is performed as follows.

Specifically, the read data information storage area 109 has a state shown in FIG. 4E, and the data of two sectors for the second memory addresses 112 “0x0200” and “0x0600” are sequentially read, so that the validity flag 111 corresponding to the second memory address 112 for which the reading has been completed is set to “INVALID.”

### 2. Second Embodiment

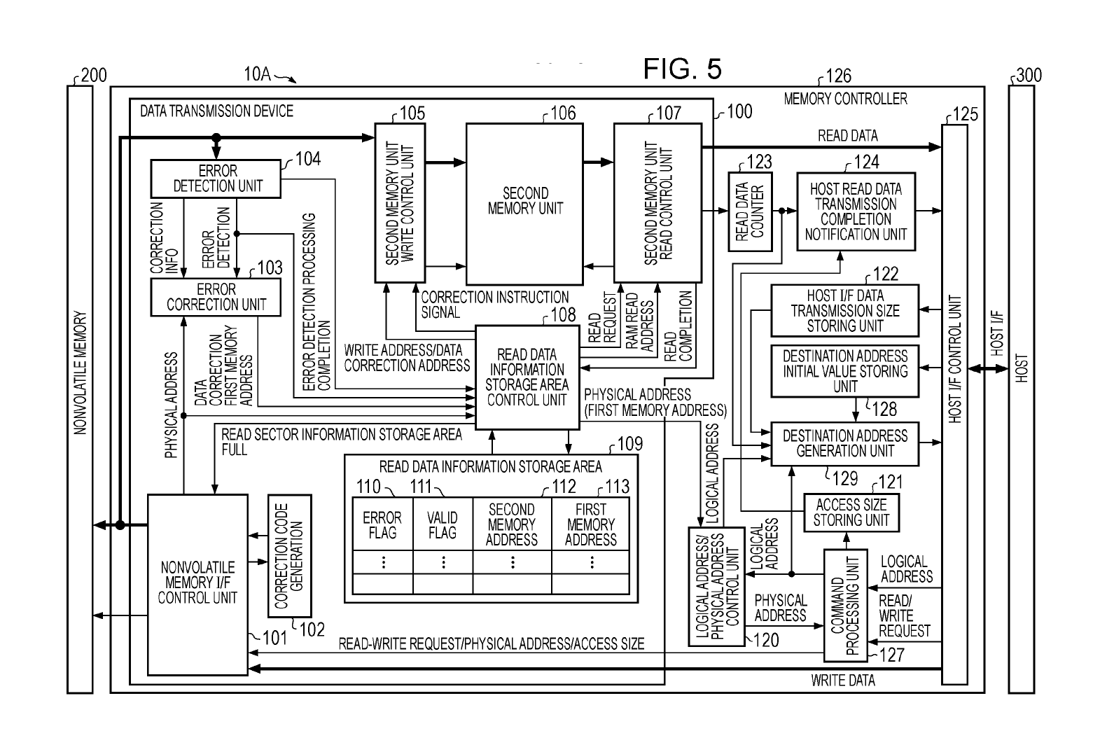

FIG. 5 is a diagram illustrating a configuration of the memory system obtained by applying the data transmission device according to the second embodiment of the disclosure.

According to the second embodiment, the first memory device 200 is a nonvolatile memory, and the memory system 10A is connected to the host device 300.

In the NAND flash memory, which is one type of nonvolatile memory 200, a technique of converting the address (hereinafter, referred to as a logical address) from the host device 300 to a memory address (hereinafter, referred to as a physical address) and accessing the NAND flash memory (hereinafter, referred to as logical-physical conversion) is used often.

According to the second embodiment, the disclosure is applied to a system that uses logical-physical conversion.

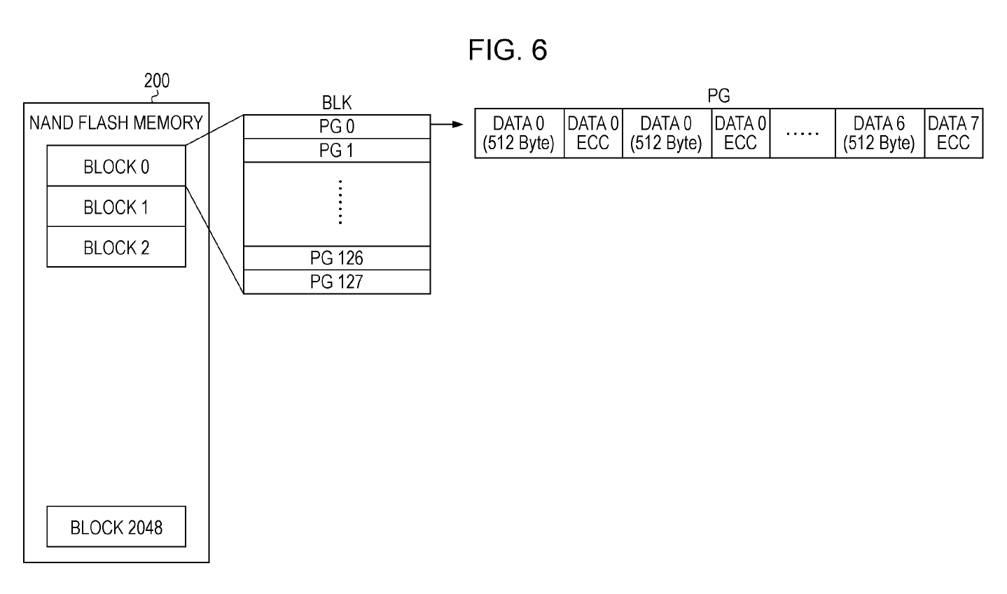

FIG. 6 is a diagram illustrating fundamental characteristics of the NAND flash memory.

As shown in FIG. 6, the NAND flash memory 200 is a device capable of reading and writing data in the unit of page PG. The page size may be set to 2 KB, 4 KB, 8 KB, or various values depending on the type of device.

Since rewriting is inhibited, if data are not removed once, it is not possible to write data again. Data are removed only in the unit of block, and a single block BLK includes a plurality of pages.

In the memory system 10A according to the second embodiment of the disclosure, the data transmission device 100 is included in the memory controller, and the following elements are added to the configuration according to the first embodiment.

Basically, the memory control device includes a data transmission device 100 and a memory controller.

The memory system 10A additionally includes a logical/physical address control unit 120, an access size storing unit 121, a host I/F data transmission size storing unit 122, and a read data counter 123.

Furthermore, the memory system 10A additionally includes a read data transmission completion notification unit 124, a host I/F control unit 125, a command processing unit 127, a destination address initial value storing unit 128, and a destination address generation unit 129 to configure a memory controller 126.

In the memory system 10A, the memory controller 126 is connected to the host device 300.

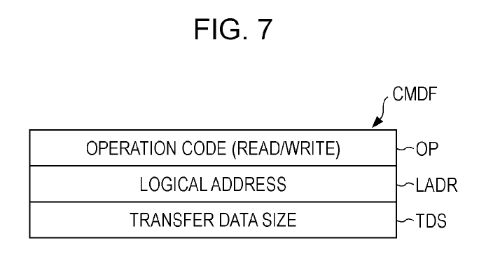

FIG. 7 is a diagram illustrating a command format example.

The command format CMDF includes an operation code OP, a logical address LADR, and a transmission data size TDS.

During the data reading, the host device 300 establishes the initial address of the destination address to which the read data are transmitted in the destination address initial value storing unit 128.

The logical address and the size of the data read by the host device 300 are notified to the memory controller 126 as a read command (FIG. 7).

For example, the command is set in an internal register of the command processing unit 127 through register accessing from the host device 300.

The command processing unit 127 receives the read command and stores the read size in the access size storing unit 121. In addition, the command processing unit 127 outputs the logical address to be accessed to the logical/physical address control unit 120 and the destination address generation unit 129. In addition, the command processing unit 127 receives the physical address from the logical/physical address control unit 120 and accesses the nonvolatile memory 200.

When the read data expand across a plurality of pages, the physical addresses are generated at a plurality of times to access the nonvolatile memory 200. The host I/F data transmission size storing unit 122 defines a size (host I/F data transmission size) of the data transmitted to the host device 300 at a single time.

The read data counter 123 counts the read data.

When the read data are transmitted from the memory controller 126 to the host device 300, the memory controller 126 serves as a bus master to perform data transmission.

The processes of reading the data from the nonvolatile memory (first memory device) 200, writing the data to the second memory unit 106, and reading the read data using the second memory unit read control unit 107 are the same as those of the first embodiment.

Here, generation of the address added to the read data will be described.

First, the physical address (first memory address) corresponding to the read data is converted into the logical address using the logical/physical address control unit 120 and is output to the destination address generation unit 129.

The destination address generation unit 129 generates the destination address of the host device 300 added to the read data.

Generation of the destination added to the read data in the host device 300 is performed based on the following information. The destination is generated based on the destination address stored in the destination address initial value storing unit 128, the logical address received using the command, and the logical address corresponding to the read data. In addition, the destination is generated based on the count value of the read data from the read data counter 123 and the host I/F data transmission size from the host I/F data transmission size storing unit 122.

Specifically, the destination address generation unit 129 subtracts the logical address received using the command from the value of the logical address corresponding to the read data and adds the value of the address stored in the destination address initial value storing unit 128 to the subtraction result, so as to output the result as a host address.

In a case where the count value of the read data reaches the host I/F transmission size, and the logical address from the logical/physical address control unit 120 remains in the previous one, the destination address generation unit 129 adds the host I/F transmission size to the current host address. In addition, the destination address generation unit 129 outputs the new host address to the host I/F control unit 125.

In a case where the logical address from the logical/physical address control unit 120 is changed, the destination address generation unit 129 subtracts the logical address received using the command from the value of the logical address corresponding to the read data. The destination address generation unit 129 adds the value of the address stored in the destination address initial value storing unit 128 to the subtraction result and outputs it as the host address.

If it is detected that transmission of the data corresponding to the access size of the access size storing unit 121 and the read size from the host from the count value of the read data counter 123 is completed, the read data transmission completion notification unit 124 notifies the host I/F control unit 125 of this fact.

The host I/F control unit 125 receives the read data and the address thereof and converts them to the protocol of the host I/F. The converted data and the address are transmitted to the host device 300. As the data corresponding to the size in the read request are completely transmitted, an interrupt signal is generated for the host.

### 3. Third Embodiment

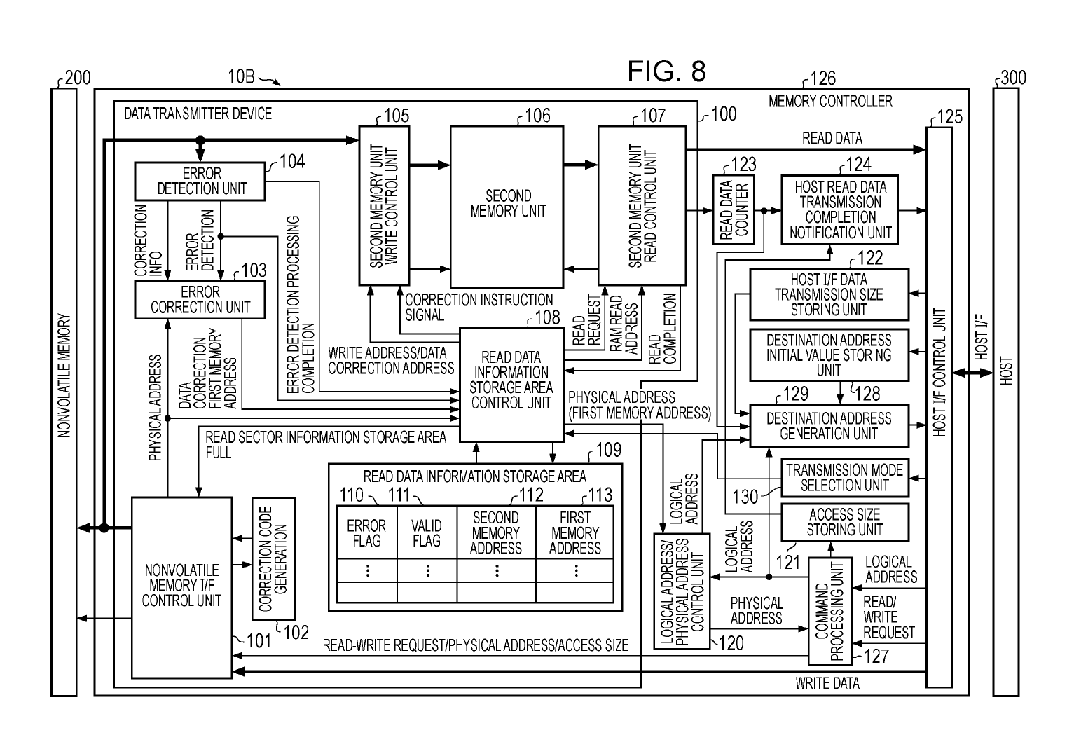

FIG. 8 is a diagram illustrating a configuration of the memory system obtained by applying the data transmission device according to the third embodiment of the disclosure.

The memory system 10B according to the third embodiment is different from the memory system 10A according to the second embodiment as follows.

Specifically, the memory system 10B according to the third embodiment additionally has a function of the read data information recording area control unit 108 and a function of the transmission mode selection unit 131.

The read data information recording area control unit 108 has a priority mode and a sequential mode. In the priority mode, the address having the validity flag 111 set to “VALID” is selected as a read address with a higher priority.

In the sequential mode, when the data from the first memory device (nonvolatile memory) 200 are written to the second memory unit 106, the data are written according to the address sequence of the second memory unit 106. The read address is selected in the address sequence of the second memory unit 106 at the time of reading.

The transmission mode selection unit 130 has a function of setting which of the priority mode and the sequential mode is used to transmit the data, which may be set from the host device 300.

### 4. Fourth Embodiment

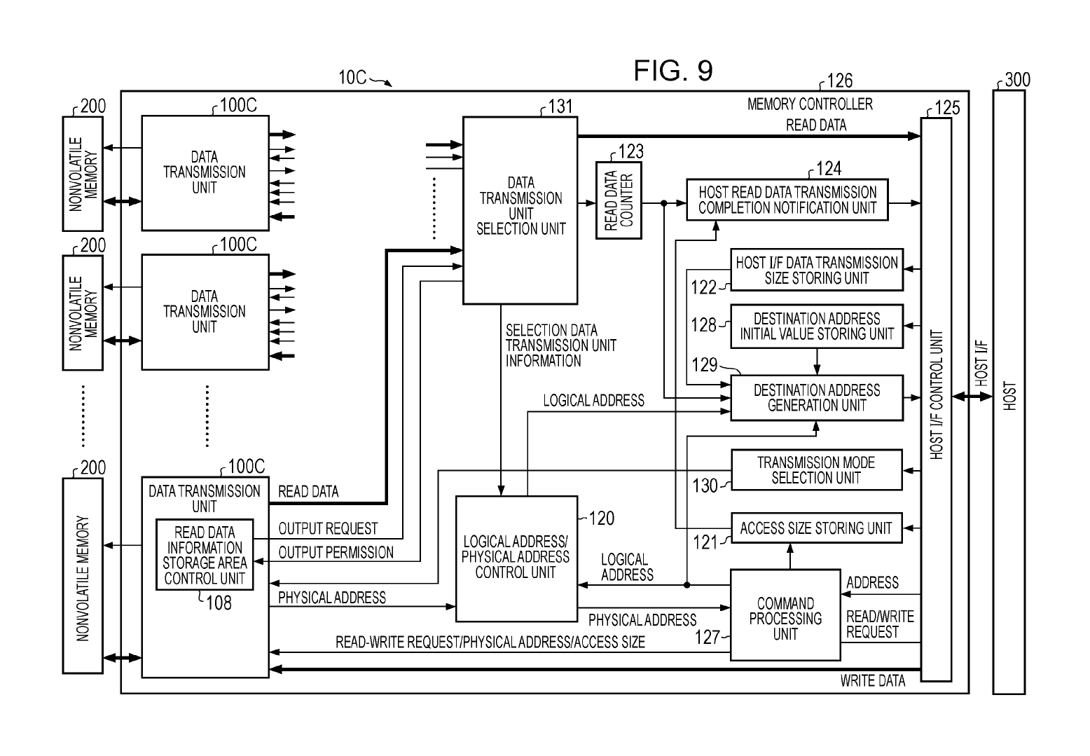

FIG. 9 is a diagram illustrating a configuration of the memory system obtained by applying the data transmission device according to the fourth embodiment of the disclosure.

The memory system 10C according to the fourth embodiment is different from the memory system 10A according to the second embodiment as follows.

Specifically, the memory system 10C according to the fourth embodiment has a plurality of data transmission units 100C corresponding to the data transmission device 100 and a plurality of nonvolatile memories 200, and the memory controller 126 additionally has a data transmission unit selection unit 131. In addition, the memory system 10C has a function of selecting which data transmission unit 100C is used to output data to the host I/F control unit 125.

The read data information recording area control unit 108 of the data transmission unit 100C has the following functions in addition to the functions described in the first embodiment.

The read data information recording area control unit 108 outputs the output request to the data transmission unit selection unit 131 before the read request is issued to the second memory unit read control unit 107. The read data information recording area control unit 108 issues the read request to the second memory unit read control unit 107 after the output permission is received from the data transmission unit selection unit 131.

The data transmission unit selection unit 131 notifies the data transmission unit 100C, which is currently selected, to the logical/physical address control unit 120. The logical/physical address control unit 120 generates the logical address based on the data transmission unit 100C, which is currently selected, and the physical address.

### 5. Fifth Embodiment

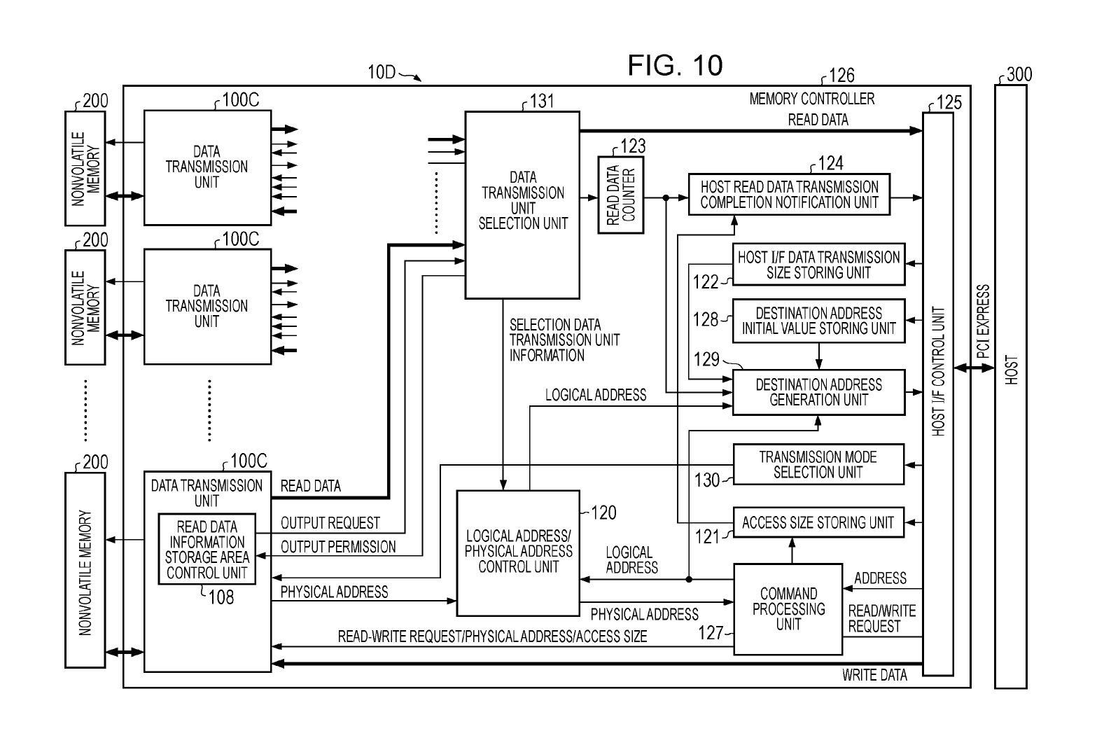

FIG. 10 is a diagram illustrating a configuration of the memory system obtained by applying the data transmission device according to the fifth embodiment of the disclosure.

The memory system 10D according to the fifth embodiment is obtained by subordinately conceptualizing the memory system 10C according to the fourth embodiment. The interface with the host device 300 is a PCI Express I/F as an example of the serial transmission I/F.

PCI Express is capable of high-speed serial transmission of 2.5 Gbps (Gen1), data communication using a protocol, and the like. PCI Express is widely used as an internal bus for a personal computer (PC) or a built-in device, or an Express Card bus.

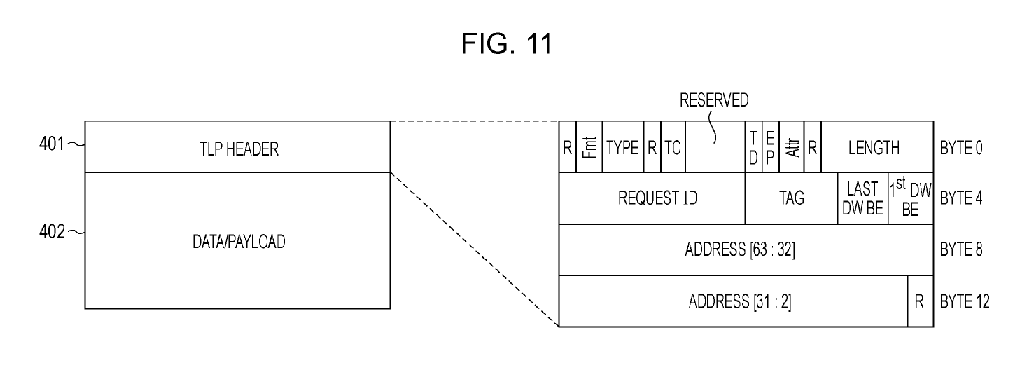

FIG. 11 is a diagram illustrating a format of the packet used in PCI Express.

In PCI Express, a TLP header 401 is added to the data. According to embodiments of the disclosure, the destination address is set to the address of the TLP header 401, and the read data are set to the data payload 402 when the read data are transmitted from the memory controller 126 to the host device 300.

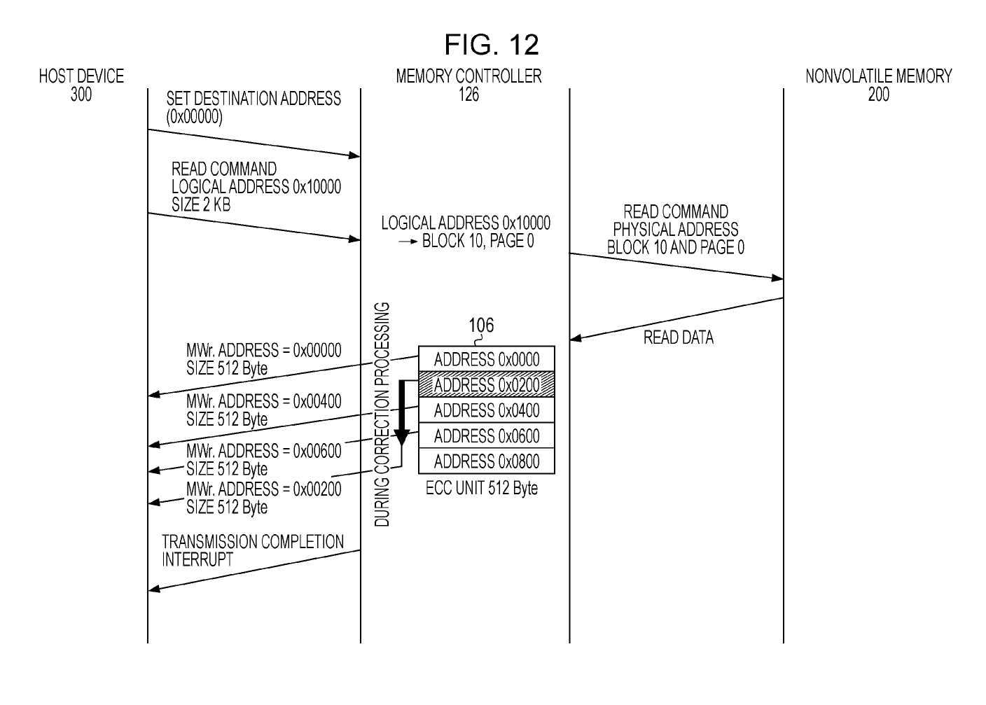

The data transmission flow in a case where the example of the data reading of the first memory device 200 exemplified in conjunction with FIG. 4 is performed according to the fifth embodiment is illustrated in FIG. 12.

FIG. 12 illustrates data transmission between the host device 300 and the memory controller 126 and data transmission between the memory controller 126 and the nonvolatile memory 200.

The destination address (0x00000) of the read data is transmitted (set) from the host device 300 to the memory controller 126 through the PCI Express I/F. In addition, the read command, the logical address 0x10000, and each piece of the information having a data size of 2 KB are transmitted.

The memory controller 126 obtains the block BLK10 and the page PG0 as a physical address by using the received logical address 0X00000 and transmits the read command and the physical address including the block BLK10 and the page PG0 to the nonvolatile memory 200.

In response, the nonvolatile memory 200 transmits the read data to the memory controller 126.

The memory controller 126 performs control such that data of 512 bytes are recorded in the second memory unit 106, data having no error are output first, and data correction is performed for the data to be corrected. The resulting data are transmitted to the host device 300.

Specific processing has been described in detail in conjunction with the first embodiment, and description thereof will not be repeated here.

### 6. Sixth Embodiment

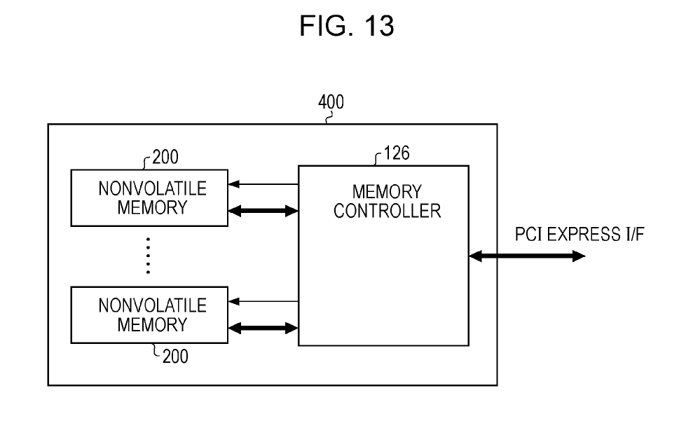

FIG. 13 is a diagram illustrating a configuration of the memory system obtained by applying the data transmission device according to the sixth embodiment of the disclosure.

According to the sixth embodiment, the memory controller and the nonvolatile memory are mounted on the Express Card to provide a memory card 400.

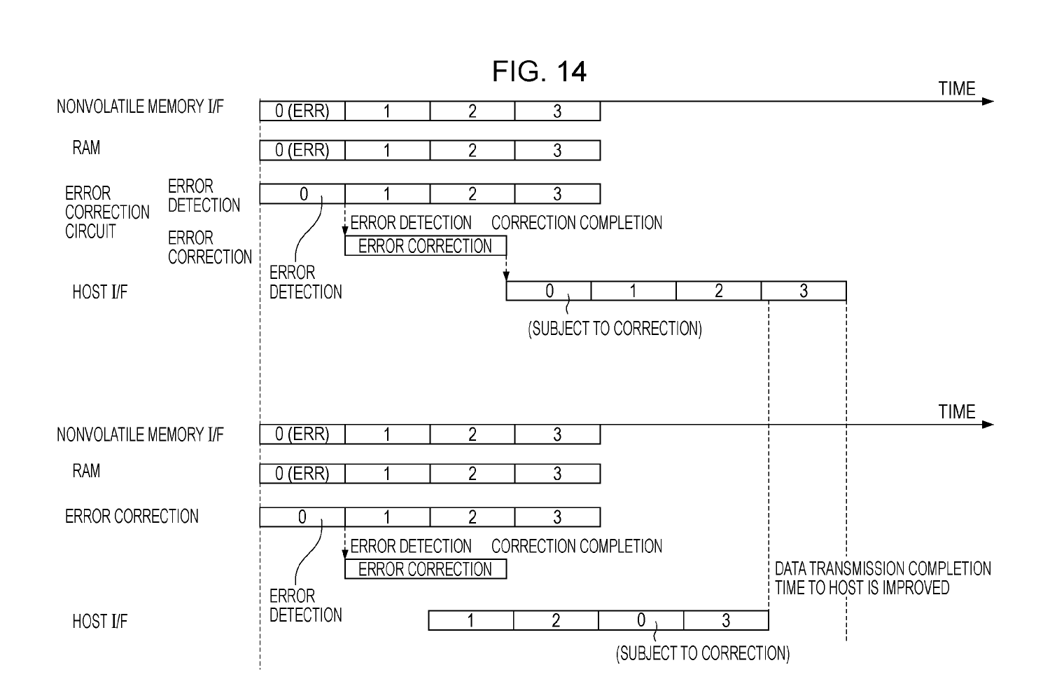

FIG. 14 is a diagram illustrating an effect obtained by firstly outputting error-free data according to the sixth embodiment.

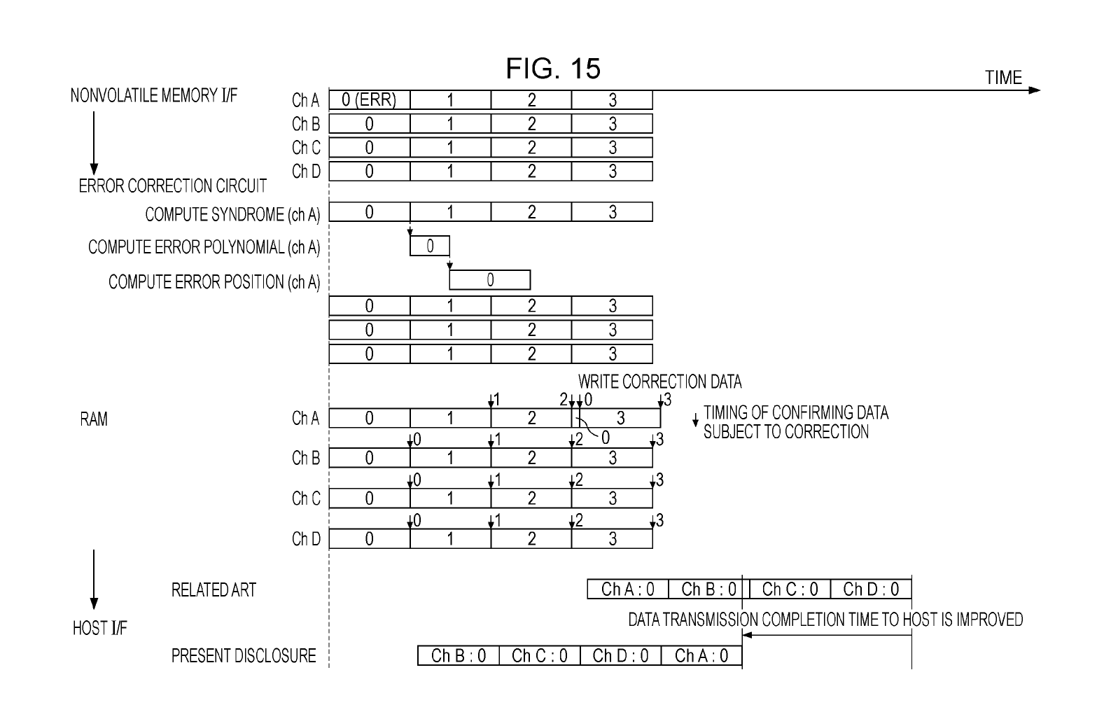

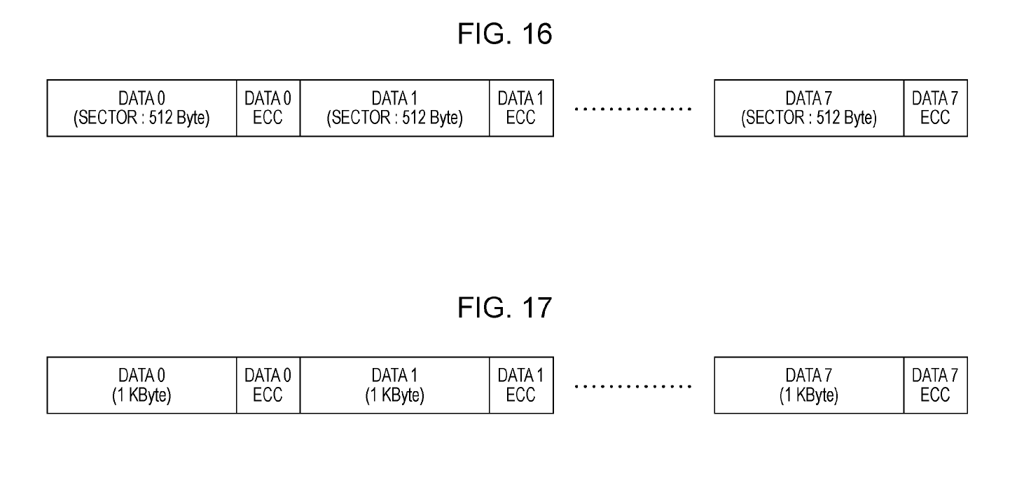

FIG. 15 is a diagram illustrating an effect obtained by firstly outputting error-free data in a case where a plurality of nonvolatile memory I/F are provided according to the sixth embodiment.

According to the embodiments described above, the following effects can be obtained.

As shown in FIGS. 14 and 15, even when the error correction takes long time, it is possible to reduce time necessary to transmit data by firstly outputting subsequent error-free data in comparison with the related art.

According to the embodiment of the disclosure, the host switches between a priority mode in which the data transmission to the host device is performed starting from the data subject to the error correction and a sequential mode in which data transmission to the host is performed sequentially as read from the memory.

As a result, it is possible to prepare for various types of host devices by selecting the sequential mode for a host device incapable of transmitting data in a priority mode in which data are not sequentially read.

The method described above in detail may be embodied as a program conforming to the aforementioned sequence and may be executed by a computer such as a central processing unit (CPU).

Such a program may be stored in recording media such as a semiconductor memory, a magnetic disc, an optical disc, and a floppy (registered trademark) disk, or may be configured to access a computer into which the recording media are set and execute the aforementioned program.

The present disclosure contains subject matter related to that disclosed in Japanese Priority Patent Application JP 2010-281566 filed in the Japan Patent Office on Dec. 17, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A data transmission device comprising:
a second memory device that stores data transmitted from a first memory device that stores data incorporating an error correction code (ECC);
an error detection unit that detects an error using data before the correction and the error correction code (ECC);
an error correction unit that obtains an error position from error information and an error detection signal from the error detection unit and corrects error data based on an address of the second memory device to which data containing an error are written and error position information;
a data information storage area including a plurality of areas for storing a first memory address of the first memory device of a data transmission source, a second memory address of the second memory device of a data transmission destination, an error signal indicating whether or not an error is detected in transmission data, and an validity signal indicating whether or not data stored in the second memory device are valid after completing the error correction; and
a control unit that outputs a second memory validity address which is a memory address in which data are valid out of data stored in the second memory device, reads data from the second memory validity address of the second memory device, and transmits an address of the first memory device corresponding to the second memory validity address along with the read data.

2. A data transmission device according to claim 1, wherein the control unit performs control such that
in a case where, as a data read request is received, the validity signal of the data information storage area indicates invalid, the error signal indicates no-error detection, and it is indicated that there is an empty area in the second memory device, write addresses of the second memory device are established, and the read data are written to the second memory device,
in a case where no error is detected as a result of an error check of the read data, the validity signal corresponding to an address designated as a write address of the second memory device is set to “VALID,” the error signal is set to “NO,” and an address of the first memory device that has been read and a write address of the second memory device are set in the first memory address, and
in a case where an error is detected as a result of an error check of the read data, the validity signal corresponding to an address designated as a write address of the second memory device is set to “INVALID,” the error signal is set to “YES,” and an address of the first memory device that has been read and a write address of the second memory device in the first memory address.

3. The data transmission device according to claim 1, wherein the control unit performs control such that
in a case where a second memory address having the validity signal indicated as effective exists in the data information storage area when data are read from the second memory device, a read address of the second memory device and a read request is output, data from the second memory device of which address are designated is read, and the data and the first memory address corresponding to the second memory address are output, and
as reading of the data is completed, the validity signal corresponding to the read address of the second memory device of the data information storage area is set to “INVALID.”

4. A memory control device comprising:
at least one data transmission device that performs data transmission between first memory devices; and
a memory controller that performs transmission control with at least a host device,
wherein the data transmission device includes
a second memory device that stores data transmitted from the first memory device that stores data incorporating an error correction code (ECC),
an error detection unit that detects an error using data before correction and an error correction code (ECC),
an error correction unit that obtains an error position based on error information and an error detection signal from the error detection unit, and corrects error data based on error position information and an address of the second memory device to which data containing an error have been written,
a data information storage area having a plurality of areas for storing a first memory address of the first memory device of the data transmission source, a second memory address of the second memory device of a data transmission destination, an error signal indicating whether or not an error has been detected in transmission data, and an validity signal indicating whether or not data stored in the second memory device are valid after completing the error correction, and
a first control unit that outputs a second memory validity address which is a memory address in which data are valid out of the data stored in the second memory device, reads data from a second memory validity address of the second memory device, and transmits an address of the first memory device corresponding to the second memory validity address along with the read data, and
wherein the memory controller includes
an address control unit that receives a read command from the host device, converts a read logic address into a first memory physical address, and converts the physical address into a logical address, and
a transmission control system that also transmits a logical address when data are output to the host device, and notifies a host of an interrupt signal indicating that data transmission is completed when transmission of data having a size requested by the read command is completed.

5. The memory control device according to claim 4, wherein the first control unit performs control such that
as a data read request is received, in a case where the validity signal of the data information storage area indicates invalid, the error signal indicates no-error detection, and there is an empty area in the second memory device, a write address of the second memory device is set, and the read data are written to the second memory device,
in a case where no error is detected as a result of an error check of the read data, the validity signal corresponding to an address designated by the write address of the second memory device is set to “VALID,” the error signal is set to “NO,” and an address of the first memory device read to the first memory address is set,
in a case where an error is detected as a result of an error check of the read data, an validity signal corresponding to an address designated by the write address of the second memory device is set to “INVALID,” the error signal is set to “YES,” and the address of the first memory device that has been read is set in the first memory address.

6. The memory control device according to claim 4, wherein the first control unit performs control to read data from the second memory device, such that
in a case where a second memory address having the validity signal indicated as effective exists in the data information storage area, a read request and a read address of the second memory device are output, and data are read from the second memory device of which address are designated to output the data and the read logical address, and
as reading of the data is completed, the validity signal corresponding to the read address of the second memory device of the data information storage area is set to “INVALID.”

7. The memory control device according to claim 4, wherein the memory controller includes:
a destination address storing unit that stores an initial value of a destination address designated to return the read data to the host device;
a command processing unit that receives a read command from the host device having a read address and a read size, and outputs an address of the first memory device read by analyzing the command;
an address control unit that converts a read logical address to a first memory physical address, and converts the physical address into a logical address;
an interface control unit that controls an interface of the first memory device and reads data based on a physical address notified from the command processing unit;
a destination address generation unit that generates an initial value of an address designated to return the read data to the host device, a logical address corresponding to the read data, and a destination address of the host device for returning data read from the read address designated by the read command; and
a transmission control system that also transmits the destination address when the read data are output to the host device, and notifies the host of an interrupt signal indicating that data transmission is completed when transmission of data having a size requested by the read command is completed.

8. The memory control device according to claim 4, wherein the memory controller includes a plurality of interfaces between the data transmission device and the first memory device, and has a function of selecting the data transmission device for receiving an output request from the data transmission device and performing data transmission.

9. The memory control device according to claim 4, wherein the data transmission device has a sequential mode in which data are transmitted sequentially as stored in the second memory device and a priority mode in which an address having an validity signal set to “VALID” in the data information storage area is selected as a read address with a higher priority, and
wherein which of the sequential mode and the priority mode is used to transmit data can be set.

10. A memory system comprising:
a host device;
a first memory device that stores data incorporating an error correction code (ECC); and
a memory control device that performs data transmission control between the host device and the first memory device,
wherein, the memory control device has
at least one data transmission device that performs data transmission between first memory devices, and
a memory controller that performs transmission control with at least a host device,
wherein the data transmission device has
a second memory device that stores data transmitted from the first memory device which stores the data incorporating the error correction code (ECC),
an error detection unit that detects an error using the data before correction and the error correction code (ECC),
an error correction unit that obtains an error position from error information and an error detection signal from the error detection unit, and corrects error data based on error position information and an address of the second memory device to which data containing an error have been written,
a data information storage area having a plurality of areas for storing a first memory address of the first memory device of a data transmission source, a second memory address of the second memory device of a data transmission destination, an error signal indicating whether or not an error is detected in transmission data, and an validity signal indicating whether or not the data stored in the second memory device are valid after completing the error correction, and
a first control unit that outputs a second memory validity address which is a memory address in which data are valid out of the data stored in the second memory device, reads data from the second memory validity address of the second memory device, and transmits an address of the first memory device corresponding to the second memory validity address along with the read data, and
wherein the memory controller includes
an address control unit that receives a read command from the host device, converts a read logical address into a first memory physical address and converts the physical address into a logical address, and
a transmission control system that also transmits a logical address when data are output to the host device, and notifies the host of an interrupt signal indicating that data transmission is completed when transmission of data having a size requested by the read command is completed.

11. The memory system according to claim 10, wherein the memory controller includes
a destination address storing unit that stores an initial value of a destination address designated to return the read data to the host device,
a command processing unit that receives a read command from the host device having a read address and a read size, and outputs an address of the first memory device read by analyzing the command,
an address control unit that converts a read logical address to a first memory physical address, and converts the first memory physical address into a logical address,
an interface control unit that controls an interface of the first memory device and reads data based on a physical address notified from the command processing unit,
a destination address generation unit that generates an initial value of an address designated to return the read data to the host device, a logical address corresponding to the read data, and a destination address of the host device for returning data read from the read address designated by the read command, and
a transmission control system that also transmits the destination address when the read data are output to the host device, and notifies the host of an interrupt signal indicating that data transmission is completed when transmission of data having a size requested by the read command is completed.

12. The memory system according to claim 10, wherein the data transmission device has a sequential mode in which data are transmitted sequentially as stored in the second memory device and a priority mode in which an address having an validity signal set to “VALID” in the data information storage area is selected as a read address with a higher priority, and
the host device can set which of the sequential mode and the priority mode is used to transmit data.

13. The memory system according to claim 10, wherein the host device and the memory controller are connected to each other through a serial transmission interface.
